(19) United States
(12) Patent Application Publication
(10) Pub. No.: US 2024/0348214 A1
(43) Pub. Date: Oct. 17, 2024

(54) DIGITAL AUDIO AMPLIFIER, CHIP, AND ELECTRONIC DEVICE

(71) Applicant: Shanghai Awinic Microelectronics Technology Co., Ltd., Shanghai (CN)

(72) Inventors: Kangqi LIU, Shanghai (CN); Jianing ZHOU, Shanghai (CN)

(73) Assignee: Shanghai Awinic Microelectronics Technology Co., Ltd., Shanghai (CN)

(21) Appl. No.: 18/753,288

(22) Filed: Jun. 25, 2024

Related U.S. Application Data
(63) Continuation of application No. PCT/CN2023/125016, filed on Oct. 17, 2023.

(30) Foreign Application Priority Data
Mar. 17, 2023 (CN) 202310269376.1

(51) Int. Cl. H03F 3/217

(52) U.S. Cl. CPC H03F 3/2175; H03F 3/2173; H03F 3/2178; H03F 2200/03; H03F 2200/351

(57) ABSTRACT

The present disclosure provides a digital audio amplifier, a chip, and an electronic device. The amplifier includes: a digital-to-analog conversion section configured to convert an inputted pulse width modulation signal into an analog signal, the pulse width modulation signal is obtained from modulation of a to-be-amplified digital audio signal; a drive section configured to amplify the analog signal and then output a drive signal; and an audio amplification section configured to amplify the drive signal into a first amplified signal at a first amplification factor when a voltage is provided by a first voltage source; and amplify the drive signal into a second amplified signal at a second amplification factor when a voltage is provided by a second voltage source; wherein the voltage of the first voltage source is lower than the voltage of the second voltage source, and the first amplification factor is smaller than the second amplification factor.

### CROSS REFERENCE TO RELATED APPLICATIONS

The present disclosure is a continuation of international application No. PCT/CN2023/125016, filed on Oct. 17, 2023, which claims priority to Chinese Patent Application No. 202310269376.1 titled “DIGITAL AUDIO AMPLIFIER, CHIP, AND ELECTRONIC DEVICE” and filed with the China National Intellectual Property Administration on Mar. 17, 2023, both of which are incorporated herein by reference in their entireties.

### TECHNICAL FIELD

The present disclosure relates to the technical field of audio amplifiers, and particularly relates to a digital audio amplifier, a chip, and an electronic device.

### BACKGROUND

A class D amplifier is a digital audio amplifier. The higher the voltage source voltage at its output stage is, the larger the gain (i.e., amplification factor) is, and the larger the noise is; and otherwise, the lower the voltage source voltage at the output stage is, the smaller the gain is, and the smaller the noise is.

In the prior art, the output stage of the class D amplifier includes a single power rail, which amplifies an audio signal. The single power rail is usually provided with a voltage by a voltage source in a particular voltage range, for example, a high power supply voltage of 3.8-5.5V. This is because the single power rail of the class D amplifier is provided with a voltage by a particular pin of a component (such as a chip) on which the class D amplifier is integrated, and the particular pin is provided with a voltage by a predesigned voltage source in a set voltage range. Since the gain of the class D amplifier in the prior art is greatly limited by the high voltage source voltage, it has a single noise and gain.

However, the class D amplifier may operate in two different scenarios. One of the scenarios is a high-gain scenario, accordingly with a large noise, and the other of the scenarios is a low-noise scenario, accordingly with a small gain. As mentioned above, the class D amplifier in the prior art has a single noise and gain, and cannot satisfy the requirements of both high-gain and low-noise scenarios.

### SUMMARY

Some embodiments of the present disclosure provide a digital audio amplifier, a chip, and an electronic device. The present disclosure is introduced below from a plurality of aspects, and the embodiments and beneficial effects in the plurality of aspects can be mutually referred to.

In a first aspect, an embodiment of the present disclosure provides a digital audio amplifier, including: a digital-to-analog conversion section, a drive section, and an audio amplification section, wherein the digital-to-analog conversion section is configured to convert a to-be-amplified digital audio signal into an analog signal; the drive section is configured to perform pulse width modulation on the analog signal and then output a drive signal; and the audio amplification section is configured to amplify the drive signal into a first amplified signal at a first amplification factor when the audio amplification section is provided a voltage by a first voltage source; and amplify the drive signal into a second amplified signal at a second amplification factor when the audio amplification section is provided with a voltage of a second voltage source; wherein the voltage of the first voltage source is lower than the voltage of the second voltage source, and the first amplification factor is smaller than the second amplification factor.

According to an embodiment of the present disclosure, when the digital audio amplifier is provided with a voltage by a voltage source with a high voltage, the digital audio signal can be amplified at a large amplification factor. In this case, the gain is large and the noise is large. When the digital audio amplifier is provided with a voltage by a voltage source with a low voltage, the digital audio signal can be amplified at a small amplification factor. In this case, the gain is small, and the noise is small. Therefore, the digital audio amplifier of the present disclosure can be switched between a large gain and a small gain, so as to satisfy the requirements of both high-gain and low-noise scenarios.

In some embodiments, when the audio amplification section is provided with a voltage by the first voltage source, the drive signal outputted from the drive section is a first drive signal; and when the audio amplification section is provided with a voltage by the second voltage source, the drive signal outputted from the drive section is a second drive signal; wherein the first drive signal is a signal obtained by performing pulse width modulation on the analog signal based on a first reference signal, the second drive signal is a signal obtained by performing pulse width modulation on the analog signal based on a second reference signal, and an amplitude of the first reference signal is smaller than an amplitude of the second reference signal.

In some embodiments, the audio amplification section includes: a first field effect transistor, a second field effect transistor, a third field effect transistor, and a fourth field effect transistor, wherein a first input terminal of the first field effect transistor is configured to receive a high level signal of the first drive signal, a second input terminal of the first field effect transistor is connected to the first voltage source, and an output terminal of the first field effect transistor is connected to an output terminal of the fourth field effect transistor; the first input terminal of the second field effect transistor is configured to receive a high level signal of the second drive signal, a second input terminal of the second field effect transistor is connected to the second voltage source, and an output terminal of the second field effect transistor is connected to a second input terminal of the third field effect transistor; a first input terminal of the third field effect transistor is configured to receive a low level signal of the first drive signal or the second drive signal, and an output terminal of the third field effect transistor is grounded; a first input terminal of the fourth field effect transistor is configured to receive the high level signal of the first drive signal, and a second input terminal of the fourth field effect transistor is connected to the output terminal of the second field effect transistor and is connected to the second input terminal of the third field effect transistor.

According to an embodiment of the present disclosure, the second field effect transistor and the third field effect transistor constitute a first output stage, and the first field effect transistor, the fourth field effect transistor, and the third field effect transistor constitute a second output stage, wherein the first output stage and the second output stage share the third field effect transistor. Since the first output stage and the second output stage can be provided with voltages by different voltage sources, the audio amplification section can generate gains of different magnitudes, thereby switching between different gains, and then satisfying the requirements of both high-gain and low-noise scenarios.

In some embodiments, the first input terminal is a gate electrode, the second input terminal is a drain electrode, and the output terminal is a source electrode.

In some embodiments, when the audio amplification section amplifies the first drive signal, the first field effect transistor, the fourth field effect transistor, and the third field effect transistor operate in a linear region; and when the audio amplification section amplifies the second drive signal, the second field effect transistor and the third field effect transistor operate in a linear region.

In some embodiments, the drive section includes: an integrating unit and a driving gate unit, wherein the integrating unit is configured to perform pulse width modulation on the analog signal based on the first reference signal when the audio amplification section is provided with the voltage by the first voltage source, to output the first drive signal to the driving gate unit; and perform pulse width modulation on the analog signal based on the second reference signal when the audio amplification section is provided with the voltage by the second voltage source, to output the second drive signal to the driving gate unit; and the driving gate unit is configured to output a high level signal of the first drive signal by a first output terminal; output a high level signal of the second drive signal by a second output terminal; and output a low level signal of the first drive signal or the second drive signal by the third output terminal.

In some embodiments, the integrating unit includes: a first-stage integrator, a second-stage integrator, and a comparator, wherein the first-stage integrator is configured to integrate an amplitude difference between the analog signal and the reference signal, and then output a first integral signal; the second-stage integrator is configured to integrate an amplitude difference between the first integral signal and the reference signal, and then output a second integral signal; and the comparator is configured to compare an amplitude of the first integral signal with an amplitude of the second integral signal, and then output the drive signal based on the comparison result.

In some embodiments, the driving gate unit includes: a first driving gate, a second driving gate, and a third driving gate, and the first driving gate, the second driving gate, and the third driving gate are connected in parallel, wherein the first driving gate is configured to be switched on when a signal outputted from the integrating unit is the high level signal of the first drive signal, to serve as the first output terminal to output the high level signal of the first drive signal; the second driving gate is configured to be switched on when a signal outputted from the integrating unit is the high level signal of the second drive signal, to serve as the second output terminal to output the high level signal of the second drive signal; and the third driving gate is configured to be switched on when a signal outputted from the integrating unit is a low level signal of the first drive signal or the second drive signal, to serve as the third output terminal to output the low level signal of the first drive signal or the second drive signal.

In some embodiments, the amplifier further includes: an adaptive adjustment section configured to output a feedback signal of the first voltage source as the first reference signal when the audio amplification section is provided with the voltage by the first voltage source; and output a feedback signal of the second voltage source as the second reference signal when the digital amplification section is provided with the voltage by the second voltage source.

In some embodiments, the amplifier further includes: a feedback circuit configured to feed back the first amplified signal or the second amplified signal to an input terminal of the first-stage integrator.

In some embodiments, the first-stage integrator is further configured to: integrate a difference between the reference signal and a combined signal of the analog signal and the feedback signal, and then output the first integral signal, wherein the feedback signal is a signal fed back to the input terminal of the first-stage integrator from the feedback circuit.

In some embodiments, the digital-to-analog conversion section, the drive section, and the audio amplification section form a first amplification branch circuit of the amplifier; and the amplifier further includes a second amplification branch circuit configured to amplify a differential signal of the digital audio signal.

In some embodiments, the first amplification branch circuit and the second amplification branch circuit have an equal amplification factor for the digital audio signal.

In a second aspect, an embodiment of the present disclosure provides a chip, including the amplifier provided in the embodiments of the first aspect. The beneficial effects of the amplifier provided in any one embodiment of the first aspect may be referred to for the beneficial effects that can be achieved in the second aspect, which will not be repeated here.

In a third aspect, an embodiment of the present disclosure provides an electronic device, including the amplifier provided in the embodiments of the first aspect or the chip provided in the embodiments of the second aspect. The beneficial effects of the amplifier provided in any one embodiment of the first aspect or the chip of the electronic device provided in any one embodiment of the second aspect may be referred to for the beneficial effects that can be achieved in the third aspect, which will not be repeated here.

### BRIEF DESCRIPTION OF DRAWINGS

FIG. 1 is a schematic block diagram of a digital audio amplifier provided in an embodiment of the present disclosure;

FIG. 2 is a schematic block diagram of another digital audio amplifier provided in an embodiment of the present disclosure;

FIG. 3 is a schematic block diagram of another digital audio amplifier provided in an embodiment of the present disclosure;

FIG. 4 is a schematic circuit diagram of a digital audio amplifier provided in an embodiment of the present disclosure;

FIG. 5 is a schematic circuit diagram of an adaptive adjustment section provided in an embodiment of the present disclosure;

FIG. 6 is a schematic circuit diagram of another digital audio amplifier provided in an embodiment of the present disclosure;

FIG. 7 is a schematic circuit diagram of a normal working mode of a digital audio amplifier provided in an embodiment of the present disclosure; and

FIG. 8 is a schematic circuit diagram of a PSM mode of a digital audio amplifier provided in an embodiment of the present disclosure.

### DESCRIPTION OF EMBODIMENTS

Embodiments of the present disclosure are used to provide a digital audio amplifier. The digital audio amplifier provided in the present disclosure can be switched between high gain and low gain based on a power source voltage. When low gain is switched to, the noise is small. Therefore, the requirements of both high-gain and low-noise scenarios can be satisfied.

A class D amplifier is a switching digital audio amplifier characterized by a small size, and can be integrated into a chip of an electronic device for amplifying the digital audio signal of the electronic device. The electronic device includes, but is not limited to, a mobile phone, a notebook computer, a tablet, a Bluetooth headset, a speaker, a smart watch, a smart bracelet, and the like. Example description of the requirements of both high-gain and low-noise scenarios is provided below with a mobile phone as the electronic device.

(1) High-gain scenario. For example, in a scenario where a user uses a mobile phone to make a call, when the user turns on hands-free to make a call, a speaker plays voice of the other party. In this case, a large gain is required, and an amplifier needs to amplify a digital signal of the voice of the other party at a large amplification factor, thereby resulting in large gain and large noise. However, due to the large volume, it is not sensitive to noise, and does not affect the call quality.

(2) Low-noise scenario. For example, when a user uses a receiver of a mobile phone to make a call, the receiver plays voice of the other party. In this case, a small gain is required, but because the voice from the receiver is small, it is more sensitive to noise. In this scenario, if the noise is large, the call quality will be affected. Therefore, when the user uses the receiver to make a call, an amplifier is required to amplify a digital signal of the voice of the other party at a small amplification factor to reduce gain, reduce noise, and improve the call quality.

For the class D amplifier, the higher the voltage source voltage at an output stage (i.e., power rail) is, the larger the gain is, and accordingly, the larger the noise is; and otherwise, the lower the voltage source voltage at the output stage is, the smaller the gain is, and accordingly, the smaller the noise is. Therefore, the gain can be reduced directly by reducing the voltage source voltage at the output stage, thereby reducing the noise to satisfy the requirements of the low-noise scenario. However, after the class D amplifier in the prior art is integrated into the chip, the voltage source at its output stage is provided by a particular pin of the chip, and the voltage source voltage of the particular pin is pre-designed, thereby failing to directly switch from a voltage source with a high voltage (e.g., 6V) to a voltage source with a low voltage (e.g., 1.8V), or failing to directly switch from a voltage source with a low voltage to a voltage source with a high voltage. Since a power supply voltage at the output stage of the class D amplifier in the prior art cannot be switched between a high voltage source and a low voltage source, the class D amplifier cannot be switched between high gain and low gain, thereby failing to satisfy the requirements of both high-gain and low-noise scenarios.

In order to satisfy the requirements of both high-gain and low-noise scenarios, an embodiment of the present disclosure provides a digital audio amplifier. An audio amplification section of the digital audio amplifier of the present disclosure serves as the output stage, and can be provided with a voltage by voltage sources with different voltages, thereby producing gain effects of different magnitudes to satisfy the requirements of high-gain and low-noise scenarios.

Specific embodiments of the present disclosure will be described in detail below with reference to the drawings.

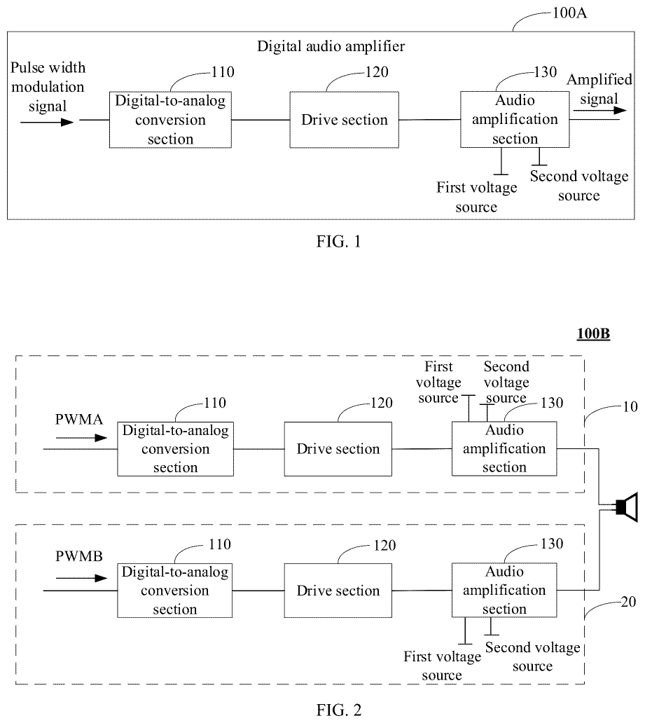

The present embodiment is used to provide a digital audio amplifier. FIG. 1 is a schematic block diagram of a digital audio amplifier 100A provided in an embodiment of the present disclosure. Referring to FIG. 1, the digital audio amplifier 100A includes: a digital-to-analog conversion section 110, a drive section 120, and an audio amplification section 130. The digital-to-analog conversion section 110 is connected to the drive section 120, and the drive section 120 is connected to the audio amplification section 130.

The digital-to-analog conversion section 110 is configured to convert a to-be-amplified digital audio signal into an analog signal.

Optionally, the digital-to-analog conversion section 110 may be an Inter Digital Analog Converter (IDAC). In some embodiments, the IDAC may be a 1-bit two-level IDAC.

The drive section 120 is configured to perform pulse width modulation on the analog signal and then output a drive signal.

Specifically, the drive section 120 may perform pulse width modulation on the analog signal inputted from the digital-to-analog conversion section 110, then output a drive signal, and input the drive signal into the audio amplification section 130.

The audio amplification section 130 is configured to amplify the drive signal into a first amplified signal at a first amplification factor when the audio amplification section 130 is provided a voltage by a first voltage source; and amplify the drive signal into a second amplified signal at a second amplification factor when the audio amplification section 130 is provided a voltage by a second voltage source; wherein the voltage of the first voltage source is lower than the voltage of the second voltage source, and the first amplification factor is smaller than the second amplification factor.

Optionally, the first amplification factor is equal to a voltage value of the first voltage source, and the second amplification factor is equal to a voltage value of the second voltage source.

As an example, when the audio amplification section 130 is provided with a voltage by a high voltage source (as an example of the second voltage source) with a voltage of 6V, the audio amplification section 130 may amplify the drive signal by 6 times and then output the first amplified signal. When the audio amplification section 130 is provided with a voltage by a low voltage source with a voltage of 1.8V (as an example of the first voltage source), the audio amplification section 130 may amplify the drive signal by 1.8 times and then output the second amplified signal.

The first amplified signal and the second amplified signal are used to drive a load speaker to play an audio, so as to amplify the to-be-amplified digital audio signal.

In an embodiment of the present disclosure, the audio amplification section of the digital audio amplifier is an output stage of the digital audio amplifier. When the voltage source voltage at the output stage is large, the digital audio amplifier can amplify the digital audio signal at a large amplification factor. In this case, the gain is large, and the noise is large. When the voltage source voltage at the output stage is small, the digital audio amplifier can amplify the digital audio signal at a small amplification factor. In this case, the gain is small, and the noise is small. Therefore, the digital audio amplifier in an embodiment of the present disclosure can be adaptively switched between high gain and low gain based on the power supply voltage at the output stage, to satisfy the requirements of both high-gain and low-noise scenarios.

Referring to FIG. 2, another embodiment of the present disclosure further provides a digital audio amplifier 100B. The digital audio amplifier 100B includes a first amplification branch circuit 10 and a second amplification branch circuit 20. Input terminals of the first amplification branch circuit 10 and the second amplification branch circuit 20 are respectively connected to a PWM modulator (not shown in the figure), and their output terminals are respectively connected to a speaker to form a loop, so as to jointly drive the speaker by an amplified signal (the first amplified signal or the second amplified signal) outputted from the first amplification branch circuit 10 and the second amplification branch circuit 20 to play an amplified audio.

Referring to FIG. 2, the first amplification branch circuit 10 and the second amplification branch circuit 20 each include a digital conversion section 110, a drive section 120, and an audio amplification section 130, wherein the second amplification branch circuit 20 is configured to amplify a differential signal of a to-be-amplified digital audio signal.

Specifically, the to-be-amplified digital audio signal may be inputted into a PWM modulator, so that the PWM modulator modulates the digital audio signal into two differential signals, such as a PWMA signal and a PWMB signal, in an AD modulation mode or a BD modulation mode, and inputs the PWMA signal and the PWMB signal respectively into the first amplification branch circuit 10 and the second amplification branch circuit 20 for amplification.

The amplification process of the first amplification branch circuit 10 and the second amplification branch circuit is explained below by an example of the PWMA signal being a voltage signal V_{PWMA} and the PWMB signal being a voltage signal V_{PWMB}:

When the audio amplification section 130 is provided with a voltage by a first voltage source, the first amplification branch circuit 10 amplifies the signal V_{PWMA} into a first amplified signal V_{OP} at a first amplification factor, and the second amplification branch circuit 20 amplifies the signal V_{PWMB} into a first amplified signal V_{ON} at the first amplification factor. It can be understood that the first amplified signal V_{OP} and the first amplified signal V_{ON} are differential signals, and the first amplified signal V_{OP} and the first amplified signal V_{ON} can jointly drive the speaker to play the amplified audio of the digital audio signal.

When the audio amplification section 130 is provided with a voltage by a second voltage source, the first amplification branch circuit 10 amplifies the signal V_{PWMA} into a second amplified signal V_{OP} at a second amplification factor, and the second amplification branch circuit 20 amplifies the signal V_{PWMB} into a second amplified signal V_{ON} at the second amplification factor. It can be understood that the second amplified signal V_{OP} and the second amplified signal V_{ON} are differential signals, and the second amplified signal V_{OP} and the second amplified signal V_{ON} can jointly drive the speaker to play the amplified audio of the digital audio signal.

It should be noted that in other embodiments, the PWMA signal and the PWMB signal may also be current signals. Their amplification process is essentially the same as the amplification process in which the PWMA signal and the PWMB signal are voltage signals, and will not be repeated here.

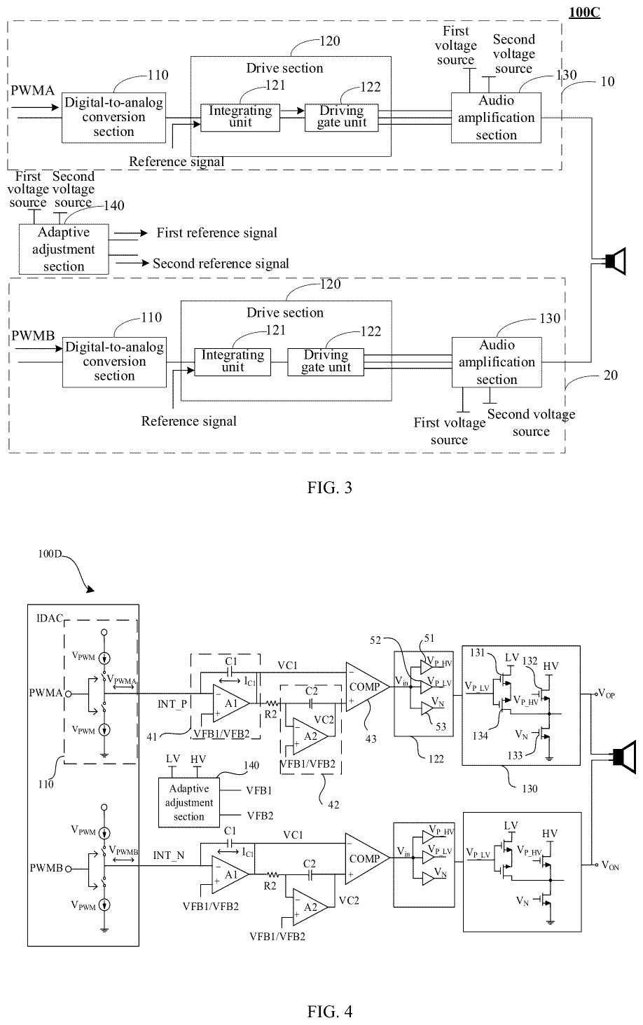

Referring to FIG. 3, another embodiment of the present disclosure further provides a digital audio amplifier 100C. Referring to FIG. 3, on the basis of the digital audio amplifiers 100A and 100B, the digital audio amplifier 100C further includes an adaptive adjustment section 140.

Voltage sources of the adaptive adjustment section 140 and the audio amplification section 130 are consistent. That is, when the audio amplification section 130 is provided with a voltage by a first voltage source, the adaptive adjustment section 140 is also provided with a voltage by the first voltage source, and when the audio amplification section 130 is provided with a voltage by a second voltage source, the adaptive adjustment section 140 is also provided with a voltage by the second voltage source.

In some embodiments, referring to FIG. 4, the adaptive adjustment section 140 internally includes a feedback circuit of a voltage source. When the adaptive adjustment section 140 is provided with a voltage by a first voltage source, a switch L1 is switched on, and the adaptive adjustment section 140 outputs a feedback signal VFB1 of the first voltage source. When the adaptive adjustment section 140 is provided with a voltage by a second voltage source, a switch L2 is switched on, and the adaptive adjustment section 140 outputs a feedback signal VFB2 of the second voltage source.

Referring to FIG. 3, the drive section 120 includes an integrating unit 121 and a driving gate unit 122.

The integrating unit 121 is configured to perform pulse width modulation on the analog signal based on the first reference signal when the audio amplification section 130 is provided with the voltage by the first voltage source, to output the first drive signal to the driving gate unit 122; and perform pulse width modulation on the analog signal based on the second reference signal when the audio amplification section 130 is provided with the voltage by the second voltage source, to output the second drive signal to the driving gate unit 122. An amplitude of the first reference signal is smaller than an amplitude of the second reference signal.

Herein, when a signal is a voltage signal, an amplitude of the signal refers to its voltage value. When a signal is a current signal, an amplitude of the signal refers to its current value.

For example, in this embodiment, the first reference signal and the second reference signal are voltage signals. Therefore, “the amplitude of the first reference signal/the amplitude of the second reference signal” refers to a voltage value of the first reference signal/a voltage value of the second reference signal. In other embodiments, when the first reference signal and the second reference signal are current signals, “the amplitude of the first reference signal/the amplitude of the second reference signal” refers to a current value of the first reference signal/a current value of the second reference signal.

When the audio amplification section 130 is provided with a voltage by the first voltage source, the adaptive adjustment section 140 is also provided with a voltage by the first voltage source. In this case, a voltage source feedback circuit of the adaptive adjustment section 140 outputs a feedback signal of the first voltage source, and inputs the feedback signal into the integrating unit 121 as the first reference signal. The integrating unit 121 performs pulse width modulation on the analog signal inputted from the digital-to-analog conversion section 110 based on the first reference signal to obtain the first drive signal, and inputs the first drive signal into the driving gate unit 122. When the audio amplification section 130 is provided with a voltage by the second voltage source, the adaptive adjustment section 140 is also provided with a voltage by the second voltage source. In this case, the voltage source feedback circuit of the adaptive adjustment section 140 outputs a feedback signal of the second voltage source, and inputs the feedback signal into the integrating unit 121 as the second reference signal. The integrating unit 121 performs pulse width modulation on the analog signal inputted from the digital-to-analog conversion section 110 based on the second reference signal to obtain the second drive signal, and inputs the second drive signal into the driving gate unit 122. The driving gate unit 122 is configured to output a high level signal of the first drive signal from a first output terminal; output a high level signal of the second drive signal from a second output terminal; and output a low level signal of the first drive signal or the second drive signal from the third output terminal.

Referring to FIG. 3, the driving gate unit 122 includes a first output terminal, a second output terminal, and a third output terminal.

When the integrating unit 121 inputs the first drive signal into the driving gate unit 122, the first output terminal of the driving gate unit 122 inputs the high level signal of the first drive signal into the audio amplification section 130, and the third output terminal of the driving gate unit 122 inputs the low level signal of the first drive signal into the audio amplification section 130. The audio amplification section 130 can amplify the first drive signal into the first amplified signal at the first amplification factor based on the high level signal and the low level signal of the first drive signal.

When the integrating unit 121 inputs the second drive signal into the driving gate unit 122, the first output terminal of the driving gate unit 122 inputs the high level signal of the second drive signal into the audio amplification section 130, and the third output terminal of the driving gate unit 122 inputs the low level signal of the second drive signal into the audio amplification section 130. The audio amplification section 130 can amplify the second drive signal into the second amplified signal at the second amplification factor based on the high level signal and the low level signal of the second drive signal.

It should be noted that in this embodiment, the first amplified signal outputted from the first amplification branch circuit 10 and the first amplified signal outputted from the second amplification branch circuit 20 are differential signals to drive the speaker to play the amplified audio when the voltage is provided by the first voltage source. The second amplified signal outputted from the first amplification branch circuit 10 and the second amplified signal outputted from the second amplification branch circuit 20 are differential signals to drive the speaker to play the amplified audio when the voltage is provided by the first voltage source.

In this embodiment, when the audio amplification section is provided with voltages by different voltage sources, the driving gate unit can selectively output signals from different output terminals based on the voltage source voltage, thereby driving the audio amplification section in different driving modes to amplify the digital audio signal at different amplification factors to achieve different gain effects, and satisfying the requirements of both high-gain and low-noise scenarios.

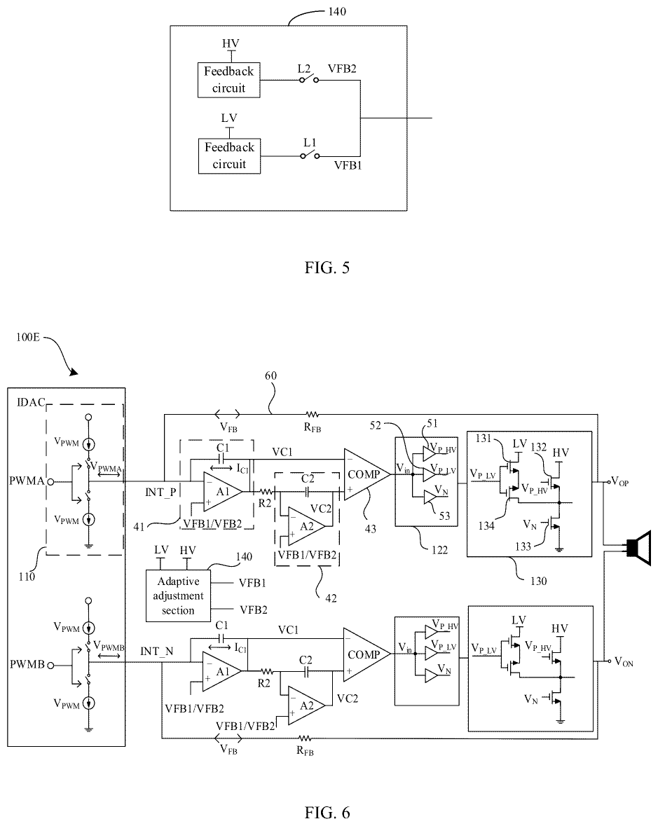

Referring to FIG. 5, another embodiment of the present disclosure provides a digital audio amplifier 100D.

The integrating unit 121 (not shown in the figure) includes a first-stage integrator 41, a second-stage integrator 42, and a comparator 43. The first-stage integrator 41 is composed of a capacitor C1 and a operational amplifier A1, and the second-stage integrator is composed of a capacitor C2 and a operational amplifier A2. The first-stage integrator 41 is connected to the second-stage integrator 42 through a resistor R2. An input terminal of the operational amplifier A1 is connected to an inverting input terminal of the comparator 43, and an output terminal of the operational amplifier A2 is connected to a non-inverting input terminal of the comparator 43.

The first-stage integrator 41 is configured to integrate an amplitude difference between the analog signal and the reference signal, and then output a first integral signal. In this embodiment, the analog signal and the reference signal are voltage signals. In other embodiments, the analog signal and the reference signal may also be current signals.

Explanation is provided below by an example of the analog signal and the reference signal being voltage signals:

specifically, the first-stage integrator 41 computes a first voltage difference between the analog signal and the reference signal (i.e., the amplitude difference between the analog signal and the reference signal), integrates the voltage difference, and then outputs a first integral signal. The first integral signal is a voltage signal.

The second-stage integrator 42 is configured to integrate an amplitude difference between the first integral signal and the reference signal, and then output a second integral signal.

Specifically, the second-stage integrator 42 computes a second voltage difference between the first integral signal and the reference signal (i.e., the amplitude difference between the first integral signal and the reference signal), integrates the second voltage difference, and then outputs the second integral signal. The second integral signal is a voltage signal.

In this embodiment, the second-stage integrator 42 and the first-stage integrator 41 constitute a two-stage integration, which can increase the loop gain in a low-frequency range of the digital audio signal, thus providing better total harmonic distortion (THD) and power supply rejection ratio (PSRR). At the same time, the resistor R2 and the capacitor C2 can introduce a compensation zero point to ensure the stability of the loop.

The comparator 43 is configured to compare the first integral signal with the second integral signal, and then output the drive signal based on the comparison result.

When a voltage value of the first integral signal is smaller than a voltage value of the second integral signal, the comparator 43 outputs a high level signal of the drive signal. When the voltage value of the first integral signal is larger than the voltage value of the second integral signal, the comparator 43 outputs a low level signal of the drive signal. In this way, the drive signal outputted from the comparator 43 is a PWM duty cycle signal, that is, the first-stage integrator 41, the second-stage integrator 42, and the comparator 43 perform pulse width modulation on the analog signal outputted from the digital-to-analog conversion section 110.

It should be noted that the processing procedure when the analog signal and the reference signal are current signals is essentially the same as the processing procedure when the analog signal and the reference signal are voltage signals, and will not be repeated here.

It should be noted that when the audio amplification section 130 is provided with a voltage by the first voltage source, the drive signal outputted from the comparator 43 is a first drive signal. When the audio amplification section 130 is provided with a voltage by the second voltage source, the drive signal outputted from the comparator 43 is a second drive signal.

In this embodiment, the first-stage integrator 41, the second-stage integrator 42, and the comparator 43 can be further used as a driving circuit to improve a pulse of the analog signal, so that the drive signal is enough to drive a field effect transistor of the audio amplification section 130, and so that the audio amplification section 130 implements the signal amplification function.

Referring to FIG. 5, the driving gate unit 122 includes: a first driving gate 61, a second driving gate 62, and a third driving gate 63, and the first driving gate 61, the second driving gate 62, and the third driving gate 63 are connected in parallel.

Optionally, the first driving gate 61, the second driving gate 62, and the third driving gate 63 may be buffers. The buffers may further increase the pulse of the drive signal, to further improve the driving capability of the drive signal, and ensure that the drive signal can drive the audio amplification section 130 to amplify the drive signal.

The first driving gate 61 is configured to be switched on when a signal outputted from the integrating unit 121 is the high level signal of the first drive signal, to serve as the first output terminal and output the high level signal of the first drive signal.

In this embodiment, when the audio amplification section 130 is provided with a voltage by the first voltage source, the signal outputted from the integrating unit 121 is the high level signal of the first drive signal.

In some embodiments, the first driving gate 61 includes a voltage source control switch. When the audio amplification section 130 is provided with a voltage by the first voltage source, the voltage source control switch is closed, and the first driving gate 61 is switched on, to serve as the first output terminal of the driving gate unit 122 and output the high level signal of the first drive signal.

In some other embodiments, the first driving gate 61 includes a logic gate. When the first driving gate 61 inputs the high level signal of a first driving new channel, the logic gate controls the first driving gate 61 to be switched on, to serve as the first output terminal of the driving gate unit 122 and output the high level signal of the first drive signal.

The second driving gate 62 is configured to be switched on when a signal outputted from the integrating unit 121 is the high level signal of the second drive signal, to serve as the second output terminal and output the high level signal of the second drive signal.

In this embodiment, when the audio amplification section 130 is provided with a voltage by the second voltage source, the signal outputted from the integrating unit 121 is the low level signal of the second drive signal.

In some embodiments, the second driving gate 62 includes a voltage source control switch. When the audio amplification section 130 is provided with a voltage by the second voltage source, the voltage source control switch is closed, and the second driving gate 62 is switched on, to serve as the second output terminal of the driving gate unit 122 and output the high level signal of the second drive signal.

In some other embodiments, the second driving gate 62 includes a logic gate. When the second driving gate 62 inputs the high level signal of the first drive signal, the logic gate controls the second driving gate 62 to be switched on, to serve as the second output terminal of the driving gate unit 122 and output the high level signal of the second drive signal.

The third driving gate 63 is configured to be switched on when a signal outputted from the integrating unit 121 is a low level signal of the first drive signal or the second drive signal, to serve as the third output terminal and output the low level signal of the first drive signal or the second drive signal.

In some embodiments, the third driving gate 63 includes a logic gate. When the integrating unit 121 inputs the low level signal of the first drive signal into the driving gate unit 122, the logic gate controls the third driving gate 63 to be switched on, to serve as the third output terminal of the driving gate unit 122 and output the low level signal of the first drive signal. When the integrating unit 121 inputs the low level signal of the second drive signal into the driving gate unit 122, the logic gate controls the third driving gate 63 to be switched on, to serve as the third output terminal of the driving gate unit 122 and output the low level signal of the second drive signal.

In this embodiment, the first driving gate 61, the second driving gate 62, and the third driving gate 63 in the driving gate unit 122 can be selectively switched on based on the voltage source voltage of the audio amplification section 130, to easily and selectively drive the field effect transistor in the audio amplification section 130, and be switched between high gain and low gain.

Referring to FIG. 5, the audio amplification section 130 includes: a first field effect transistor 131, a second field effect transistor 132, a third field effect transistor 133, and a fourth field effect transistor 134. Optionally, the first field effect transistor 131, the second field effect transistor 132, the third field effect transistor 133, and the fourth field effect transistor 134 are NMOS transistors or PMOS transistors. Explanation is provided bellow by an example of the first field effect transistor 131, the second field effect transistor 132, the third field effect transistor 133, and the fourth field effect transistor 134 being NMOS transistors:

A first input terminal of the first field effect transistor 131 is configured to receive a high level signal of the first drive signal, a second input terminal of the first field effect transistor 131 is connected to the first voltage source, and an output terminal of the first field effect transistor 131 is connected to an output terminal of the fourth field effect transistor 134.

For example, the first input terminal of the first field effect transistor 131 is a gate electrode, the second input terminal thereof is a drain electrode, and the output terminal thereof is a source electrode.

A first input terminal of the second field effect transistor 132 is configured to receive a high level signal of the second drive signal, a second input terminal of the second field effect transistor 132 is connected to the second voltage source, and an output terminal of the second field effect transistor 132 is connected to a second input terminal of the third field effect transistor 133.

As an example, the first input terminal of the second field effect transistor 132 is a gate electrode, the second input terminal thereof is a drain electrode, and the output terminal thereof is a source electrode.

A first input terminal of the third field effect transistor 133 is configured to receive a low level signal of the first drive signal or the second drive signal, and an output terminal of the third field effect transistor 133 is grounded.

As an example, the first input terminal of the third field effect transistor 133 is a gate electrode, a second input terminal thereof is a drain electrode, and the output terminal thereof is a source electrode.

A first input terminal of the fourth field effect transistor 144 is configured to receive the high level signal of the first drive signal, and a second input terminal of the fourth field effect transistor 144 is connected to the output terminal of the second field effect transistor and is connected to the second input terminal of the third field effect transistor 133.

As an example, the first input terminal of the fourth field effect transistor 134 is a gate electrode, the second input terminal thereof is a drain electrode, and the output terminal thereof is a source electrode.

In other embodiments of the present disclosure, the first field effect transistor 131, the second field effect transistor 132, the third field effect transistor 133, and the fourth field effect transistor 134 may be one of the NMOS transistors and the PMOS transistors, that is, the first field effect transistor 131, the second field effect transistor 132, the third field effect transistor 133, and the fourth field effect transistor 134 may be combined as different MOS transistors (NMOS transistors or PMOS transistors). However, the combination mode must satisfy the following conditions: the second field effect transistor 132 and the third field effect transistor 133 constitute a first half-bridge circuit, and the first field effect transistor 131 and the fourth field effect transistor 134 are connected in parallel, and then constitute, together with the third field effect transistor 133, a second half-bridge circuit, wherein the first half-bridge circuit and the second half-bridge circuit are configured to amplify the drive signal. It should be noted that other combination modes other than that shown in FIG. 5 are essentially the same as the circuit principle shown in FIG. 5, and will not be repeated here.

In this embodiment, when the audio amplification section 130 amplifies the first drive signal, the first field effect transistor 131, the fourth field effect transistor 134, and the third field effect transistor 133 operate in a linear region. When the audio amplification section 130 amplifies the second drive signal, the second field effect transistor 132 and the third field effect transistor 133 operate in a linear region.

The audio amplification section 130 is an output stage of the digital audio amplifier 100D, wherein the second field effect transistor 132 and the third field effect transistor 133 constitute a first output stage for amplifying the second drive signal. The first field effect transistor 131, the fourth field effect transistor 134, and the third field effect transistor 133 constitute a second output stage for amplifying the first drive signal. The first output stage and the second output stage share the third field effect transistor, and the first output stage and the second output stage can serve as two different power rails of the digital audio amplifier 100D.

The first field effect transistor 131 and the fourth field effect transistor 132 constitute a low-voltage high-end power transistor stage and are driven by a same driving stage, that is, driven by the second driving gate 52. The second field effect transistor 132 is a high-voltage high-end power transistor stage, and is driven by the first driving gate 51. The third field effect transistor 133 is a shared low-end power transistor stage, and is driven by the third driving gate 53.

In this embodiment, the first output stage and the second output stage of the audio amplifier 100D can be provided with voltages by voltage sources with different voltages, so that the audio amplifier 100D can produce gain effects of different magnitudes, thereby adaptively switching between different gains, and satisfying the requirements of both high-gain and low-noise scenarios.

In order to improve the linear ability of the digital audio amplifier 100D, enable the digital audio amplifier 100D to have power supply rejection ability, reduce the in-band noise introduced by nonlinearity, and improve the stability of the loop, the amplified signal can be introduced into an inverting input terminal of the first-stage integrator 41.

Referring to FIG. 6, another embodiment of the present disclosure further provides a digital audio amplifier 100E. On the basis of the digital audio amplifier 100D, the digital audio amplifier 100E further includes a feedback circuit 60, wherein the feedback circuit 60 includes a resistor R_{FB} configured to feed back the first amplified signal or the second amplified signal to the inverting input terminal of the first-stage integrator 41. In this case, the first-stage integrator 41 is further configured to integrate an amplitude difference between the reference signal and a combined signal of the analog signal and the amplified signal (the first amplified signal or the second amplified signal), and then output the first integral signal. The combined signal is a signal obtained by adding the analog signal and the amplified signal. The audio amplifier 100E in this embodiment includes two working modes: a normal working mode and a power saving mode (PSM). The two working modes of the audio amplifier 100E are explained bellow by an example of the first amplification branch circuit 10:

### Normal Working Mode

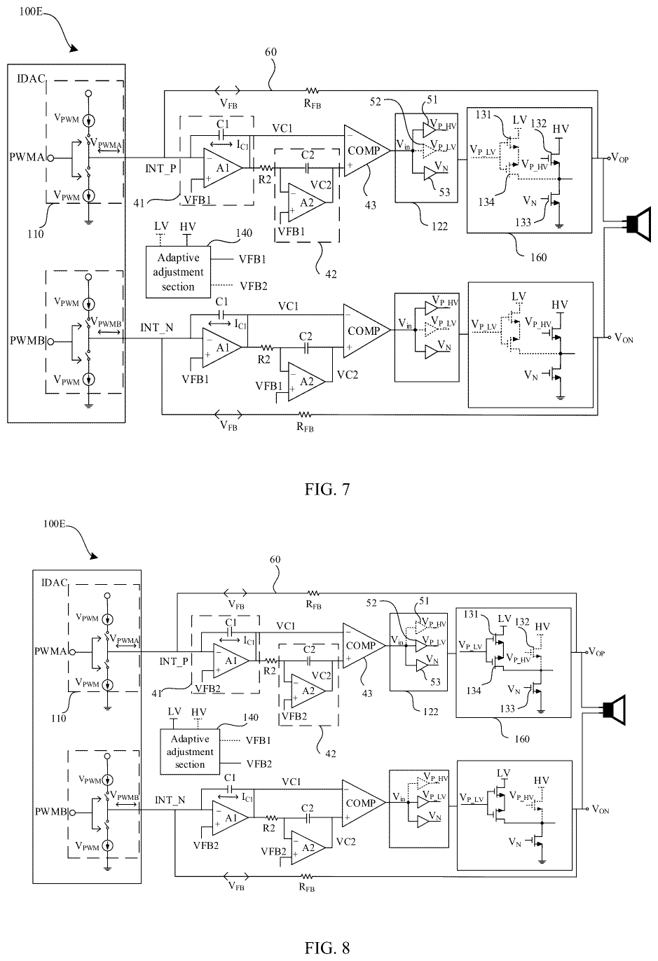

Referring to FIG. 7, when a drain electrode of the second field effect transistor 132 is provided with a voltage by a voltage source HV, the audio amplifier 100E enters the normal working mode. In this case, the adaptive adjustment section 140 is also provided with a voltage by the voltage source HV, and outputs a feedback signal VFB1 of the voltage source HV through an internal feedback circuit. The feedback signal is inputted as the first reference signal into a non-inverting input terminal of an operational amplifier A1 of the first-stage integrator 41 and a non-inverting input terminal of an operational amplifier A2 of the second-stage integrator 42 respectively.

It should be noted that in the normal working mode, the first driving gate 51 and the third driving gate 53 are switched on, while the second driving gate 52 is not switched on. Accordingly, the second field effect transistor 132 and the third field effect transistor 133 operate in a linear region, while the first field effect transistor 131 and the fourth field effect transistor 134 operate in a cut-off region.

Explanation is provided by an example of the PWMA signal inputted from a PWMA modulator being a digital signal V_{PWMA} (voltage signal): in the normal working mode, the digital-to-analog conversion section 110 converts the digital signal V_{PWMA} inputted from the PWMA modulator into an analog signal V_{PWMA}. The analog signal V_{PWMA} flows through a node INT_P, and is then inputted into an inverting input terminal of the operational amplifier A1 of the first-stage integrator 41. A feedback signal V_{FB} inputted from the feedback circuit 60 is also inputted into the inverting input terminal of the operational amplifier A1. The feedback signal VFB1 outputted from the adaptive adjustment section 140 is inputted into the non-inverting input terminal of the operational amplifier A1. The first-stage integrator 41 integrates a voltage difference between the first reference signal VFB1 and a combined signal obtained by adding voltage values of the analog signal V_{PWMA} and the feedback signal V_{FB} (as an example of the amplitude difference), and then outputs a first integral signal VC1. The first-stage integral signal VC1 is inputted into the inverting input terminal of the comparator 43, and is inputted into an inverting input terminal of the operational amplifier A2 of the second-stage integrator 42 after flowing through the resistor R2. The second-stage integrator 42 integrates a voltage difference between the first integral signal VC1 and the first reference signal VFB1 (as an example of the amplitude difference), then outputs a second integral signal VC2, and inputs the second integral signal VC2 into the non-inverting input terminal of the comparator 43. The comparator 43 compares a voltage value of the first integral signal VC1 with a voltage value of the second integral signal VC1, and outputs a first drive signal Vᵢₙ based on the comparison result.

The first drive signal Vᵢₙ is a square wave signal including a high level signal V_{P_HV} and a low level signal V_{N}. When the voltage value of the first integral signal VC1 is larger than the voltage value of the second integral signal VC2, the first drive signal Vᵢₙ is the high level signal V_{P_HV}, and when the voltage value of the first integral signal VC1 is larger than the voltage value of the second integral signal VC2, the first drive signal Vᵢₙ is the low level signal V_{N}.

The high level signal V_{P_HV} of the first drive signal Vᵢₙ flows through the first driving gate 51, and is then inputted into the second field effect transistor 132. The low level signal V_{N} of the first drive signal Vᵢₙ flows through the third driving gate 53, and is then inputted into the third field effect transistor 133, to amplify the first drive signal Vᵢₙ into a first amplified signal V_{OP} at the first amplification factor through the first output stage composed of the second field effect transistor 132 and the third field effect transistor 133, that is, amplify the digital signal V_{PWMA} into the first amplified signal V_{OP} at the first amplification factor.

It should be noted that circuits of the second amplification branch circuit 20 and the first amplification branch circuit 10 are the same, and the processing procedure of the digital signal V_{PWMB} by the second amplification branch circuit 20 is essentially the same as the processing procedure of the digital signal V_{PWMA} by the first amplification branch circuit 10. The processing procedure of the digital signal V_{PWMA} by the first amplification branch circuit 10 may be referred to for the processing procedure of the digital signal V_{PWMB} by the second amplification branch circuit 20, and will not be repeated here.

In the normal working mode, the second amplification branch circuit 20 also amplifies the digital signal V_{PWMB} into the first amplified signal V_{ON} at the first amplification factor, wherein the first amplified signal V_{OP} and the first amplified signal V_{ON} are differential signals, and the speaker can be driven by the first amplified signal V_{OP} and the first amplified signal V_{ON} to play the amplified audio. PSM mode

Referring to FIG. 8, when a drain electrode of the second field effect transistor 132 is provided with a voltage by a voltage source LV, the audio amplifier 100E enters the normal PSM mode. In this case, the adaptive adjustment section 140 is also provided with a voltage by the voltage source LV, and outputs a feedback signal VFB2 of the voltage source LV through an internal feedback circuit. The feedback signal is inputted as the second reference signal into the non-inverting input terminal of the operational amplifier A1 of the first-stage integrator 41 and the non-inverting input terminal of the operational amplifier A2 of the second-stage integrator 42 respectively.

It should be noted that in the PSM mode, the second driving gate 52 and the third driving gate 53 are switched on, while the first driving gate 51 is not switched on. Accordingly, the first field effect transistor 131, the fourth field effect transistor 134, and the third field effect transistor 133 operate in a linear region, while the second field effect transistor 132 works in a cut-off region.

Explanation is provided by an example of the PWMA signal inputted from the PWMA modulator being the digital signal V_{PWMA} (voltage signal): in the PSM mode, the digital-to-analog conversion section 110 converts the digital signal V_{PWMA} inputted from the PWMA modulator into the analog signal V_{PWMA}. The analog signal V_{PWMA} flows through a node INT_P, and is then inputted into the inverting input terminal of the operational amplifier A1 of the first-stage integrator 41. A feedback signal V_{FB} inputted from the feedback circuit 60 is also inputted into the inverting input terminal of the operational amplifier A1. The feedback signal VFB2 outputted from the adaptive adjustment section 140 is inputted into the non-inverting input terminal of the operational amplifier A1. The first-stage integrator 41 integrates a voltage difference between the second reference signal VFB2 and a combined signal obtained by adding voltage values of the analog signal V_{PWMA} and the feedback signal V_{FB}, and then outputs a first integral signal VC1. The first-stage integral signal VC1 is inputted into the inverting input terminal of the comparator 43, and is inputted into an inverting input terminal of the operational amplifier A2 of the second-stage integrator 42 after flowing through the resistor R2. The second-stage integrator 42 integrates a voltage difference between the first integral signal VC1 and the first reference signal VFB2, then outputs a second integral signal VC2, and inputs the second integral signal VC2 into the non-inverting input terminal of the comparator 43. The comparator 43 compares a voltage value of the first integral signal VC1 with a voltage value of the second integral signal VC2, and outputs a second drive signal Vᵢₙ based on the comparison result.

The second drive signal Vᵢₙ is a square wave signal including a high level signal V_{P_HV} and a low level signal V_{N}. When the voltage value of the first integral signal VC1 is larger than the voltage value of the second integral signal VC2, the second drive signal Vᵢₙ is the high level signal V_{P_HV}, and when the voltage value of the first integral signal VC1 is larger than the voltage value of the second integral signal VC2, the second drive signal Vᵢₙ is the low level signal V_{N}.

The high level signal V_{P_HV} of the second drive signal Vᵢₙ flows through the second driving gate 52, and is then inputted into the first field effect transistor 132 and the fourth field effect transistor 134. The low level signal V_{N} of the second drive signal Vᵢₙ flows through the third driving gate 53, and is then inputted into the third field effect transistor 133, to amplify the second drive signal Vᵢₙ into the second amplified signal V_{OP} at the second amplification factor through the second output stage composed of the first field effect transistor 131, the fourth field effect transistor 134, and the third field effect transistor 133, that is, amplify the digital signal V_{PWMA} into the second amplified signal V_{OP} at the second amplification factor.

It should be noted that circuits of the second amplification branch circuit 20 and the first amplification branch circuit 10 are the same, and the processing procedure of the digital signal V_{PWMB} by the second amplification branch circuit 20 is essentially the same as the processing procedure of the digital signal V_{PWMA} by the first amplification branch circuit 10. The processing procedure of the digital signal V_{PWMA} by the first amplification branch circuit 10 may be referred to for the processing procedure of the digital signal V_{PWMB} by the second amplification branch circuit 20, and will not be repeated here.

In the PSM mode, the second amplification branch circuit 20 also amplifies the digital signal V_{PWMB} into the first amplified signal V_{ON} at the second amplification factor, wherein the second amplified signal V_{OP} and the second amplified signal V_{ON} are differential signals, and the speaker can be driven by the second amplified signal V_{OP} and the second amplified signal V_{ON} to play the amplified audio. In some embodiments, when the audio amplifier 100E is switched from the normal working mode to the PSM mode, the adaptive adjustment section 140 can input the feedback signal VFB2 of the voltage source LV merely into the non-inverting input terminal of the operational amplifier A1 without the need of inputting the feedback signal into the non-inverting input terminal of the operational amplifier A2, that is to say, in this case, the non-inverting input terminal of the operational amplifier A2 is at a low level.

In this embodiment, if a voltage provided by the voltage source HV is 6V and a voltage provided by the voltage source LV is 2V, in the normal working mode, the digital audio amplifier 100E can amplify the digital audio signal by 6 times, that is, the gain is 6 times, and in the PSM mode, the digital audio signal can be amplified by 2 times, that is, the gain is 2 times. Since the gain is reduced from the original 6 times to 2 times, 3×noise reduction effects can be obtained. That is to say, when the digital audio amplifier 100 is switched from the normal working mode to the PSM mode, the noise can be reduced by 3 times.

It should be noted that in other embodiments, in the normal working mode and the PSM mode, the PWM signals (the PWMA signal and the PWMB signal) inputted from the PWM modulators (the PWMA modulator and the PWMB modulator) may also be current signals, for example, a digital signal I_{PWMA} and a digital signal I_{PWMB}. The amplification process of the digital signal I_{PWMA} and the digital signal I_{PWMB} is essentially the same as the amplification process of the digital signal V_{PWMA} and the digital signal V_{PWMB}, and will not be repeated here.

To sum up, the normal working mode of the digital audio amplifier 100E can satisfy the requirements of high-gain scenarios, and the PSM mode of the digital audio amplifier 100E can satisfy the requirements of low-noise scenarios. Therefore, the digital audio amplifier 100E of this embodiment can satisfy the requirements of both high-gain and low-noise scenarios.

The present disclosure further presents a chip, including the audio amplifier provided in the embodiments shown in FIGS. 1-8.

It should be noted that the aforementioned explanations and technical effects of the embodiments shown in FIGS. 1-8 are also applicable to the chip of this embodiment, which will not be repeated here.

The present disclosure further presents an electronic device, such as a mobile phone, a PC, a wearable device, a VR/AR device, or a vehicle device, which is not limited in the present disclosure. The electronic device provided in the present disclosure may include the audio amplifier provided in the embodiments shown in FIGS. 1-8 or may include the chip of the audio amplifier provided in the embodiments shown in FIGS. 1-8.

It should be noted that the aforementioned explanations and technical effects of the embodiments shown in FIGS. 1-8 are also applicable to the electronic device of this embodiment, which will not be repeated here.

In the drawings, some structural or methodological features may be shown in a particular arrangement and/or sequence. However, it should be understood that such particular arrangement and/or sequencing may not be required. On the contrary, in some embodiments, the features may be arranged in a manner and/or sequence different from that shown in the illustrative figures. Additionally, the inclusion of the structural or methodological features in a particular figure does not mean to imply that such features are required in all embodiments, and in some embodiments, these features may not be included or may be combined with other features.

It should be noted that in the examples and description of this patent, relational terms such as first and second are only used to distinguish one entity or operation from another entity or operation, and do not necessarily require or imply existence of any of such actual relationship or sequence between these entities or operations. Further, the terms such as “comprising”, “including” or any other variation thereof are intended to encompass non-exclusive inclusions, such that a process, a method, an article, or a device that includes a series of elements not only includes those elements, but also includes other elements that are not explicitly listed, or further includes elements that are inherent to such a process, a method, an article, or a device. In case of no more constraints, an element defined by the wording “comprise a . . . ” does not preclude the existence of additional identical elements in a process, a method, an article, or a device that includes the element.

While the present disclosure has been illustrated and described with reference to some preferred embodiments of the present disclosure, it will be understood by those of ordinary skill in the art that various alterations may be made in form and detail without departing from the spirit and scope of the present disclosure.

1. A digital audio amplifier, comprising:
a digital-to-analog conversion section;
a drive section; and
an audio amplification section, wherein:
the digital-to-analog conversion section is configured to convert a to-be-amplified digital audio signal into an analog signal;
the drive section is configured to perform pulse width modulation on the analog signal and then output a drive signal; and
the audio amplification section is configured to amplify the drive signal into a first amplified signal at a first amplification factor when the audio amplification section is provided with a first voltage by a first voltage source, and amplify the drive signal into a second amplified signal at a second amplification factor when the audio amplification section is provided with a second voltage by a second voltage source, wherein the first voltage of the first voltage source is lower than the second voltage of the second voltage source, and the first amplification factor is smaller than the second amplification factor.

2. The amplifier according to claim 1, wherein:
when the audio amplification section is provided with the first voltage by the first voltage source, the drive signal outputted from the drive section is a first drive signal;
when the audio amplification section is provided with the second voltage by the second voltage source, the drive signal outputted from the drive section is a second drive signal;
the first drive signal is a signal obtained by performing pulse width modulation on the analog signal based on a first reference signal;
the second drive signal is a signal obtained by performing pulse width modulation on the analog signal based on a second reference signal; and
an amplitude of the first reference signal is smaller than an amplitude of the second reference signal.

3. The amplifier according to claim 2, wherein the audio amplification section comprises:
a first field effect transistor;
a second field effect transistor;
a third field effect transistor; and
a fourth field effect transistor, wherein:
a first input terminal of the first field effect transistor is configured to receive a high level signal of the first drive signal, a second input terminal of the first field effect transistor is connected to the first voltage source, and an output terminal of the first field effect transistor is connected to an output terminal of the fourth field effect transistor;
a first input terminal of the second field effect transistor is configured to receive a high level signal of the second drive signal, a second input terminal of the second field effect transistor is connected to the second voltage source, and an output terminal of the second field effect transistor is connected to a second input terminal of the third field effect transistor;
a first input terminal of the third field effect transistor is configured to receive a low level signal of the first drive signal or the second drive signal, and an output terminal of the third field effect transistor is grounded; and
a first input terminal of the fourth field effect transistor is configured to receive the high level signal of the first drive signal, and a second input terminal of the fourth field effect transistor is connected to the output terminal of the second field effect transistor and is connected to the second input terminal of the third field effect transistor.

4. The amplifier according to claim 3, wherein the first input terminal is a gate electrode, the second input terminal is a drain electrode, and the output terminal is a source electrode.

5. The amplifier according to claim 3, wherein:
when the audio amplification section amplifies the first drive signal, the first field effect transistor, the fourth field effect transistor, and the third field effect transistor operate in linear regions; and
when the audio amplification section amplifies the second drive signal, the second field effect transistor and the third field effect transistor operate in the linear regions.

6. The amplifier according to claim 2, wherein the drive section comprises an integrating unit and a driving gate unit, wherein:
the integrating unit is configured to perform pulse width modulation on the analog signal based on the first reference signal when the audio amplification section is provided with the first voltage by the first voltage source, to output the first drive signal to the driving gate unit, and perform pulse width modulation on the analog signal based on the second reference signal when the audio amplification section is provided with the second voltage by the second voltage source, to output the second drive signal to the driving gate unit; and
the driving gate unit is configured to output a high level signal of the first drive signal by a first output terminal, output a high level signal of the second drive signal by a second output terminal, and output a low level signal of the first drive signal or the second drive signal by a third output terminal.

7. The amplifier according to claim 6, wherein the integrating unit comprises a first-stage integrator, a second-stage integrator, and a comparator, wherein:
the first-stage integrator is configured to integrate an amplitude difference between the analog signal and a reference signal, and then output a first integral signal;
the second-stage integrator is configured to integrate an amplitude difference between the first integral signal and another reference signal, and then output a second integral signal; and
the comparator is configured to compare an amplitude of the first integral signal with an amplitude of the second integral signal, and then output the drive signal based on a comparison result.

8. The amplifier according to claim 6, wherein the driving gate unit comprises a first driving gate, a second driving gate, and a third driving gate, and the first driving gate, the second driving gate, and the third driving gate are connected in parallel, wherein:
the first driving gate is configured to be switched on when a signal outputted from the integrating unit is the high level signal of the first drive signal, to serve as the first output terminal to output the high level signal of the first drive signal;
the second driving gate is configured to be switched on when a signal outputted from the integrating unit is the high level signal of the second drive signal, to serve as the second output terminal to output the high level signal of the second drive signal; and
the third driving gate is configured to be switched on when a signal outputted from the integrating unit is the low level signal of the first drive signal or the second drive signal, to serve as the third output terminal to output the low level signal of the first drive signal or the second drive signal.

9. The amplifier according to claim 7, wherein the amplifier further comprises:
an adaptive adjustment section configured to output a feedback signal of the first voltage source as the first reference signal when the audio amplification section is provided with the first voltage by the first voltage source, and output a feedback signal of the second voltage source as the second reference signal when the digital amplification section is provided with the second voltage by the second voltage source.

10. The amplifier according to claim 7, wherein the amplifier further comprises:
a feedback circuit configured to feed back the first amplified signal or the second amplified signal to an input terminal of the first-stage integrator.

11. The amplifier according to claim 10, wherein the first-stage integrator is further configured to:
integrate an amplitude difference between the reference signal and a combined signal of the analog signal and a feedback signal, and then output the first integral signal, wherein the feedback signal is a signal fed back to the input terminal of the first-stage integrator from the feedback circuit.

12. The amplifier according to claim 1, wherein:
the digital-to-analog conversion section, the drive section, and the audio amplification section form a first amplification branch circuit of the amplifier; and
the amplifier further comprises a second amplification branch circuit configured to amplify a differential signal of the digital audio signal.

13. The amplifier according to claim 12, wherein the first amplification branch circuit and the second amplification branch circuit have an equal amplification factor for the digital audio signal.

14. A chip, comprising:
a digital audio amplifier, comprising:
a digital-to-analog conversion section;
a drive section; and
an audio amplification section, wherein:
the digital-to-analog conversion section is configured to convert a to-be-amplified digital audio signal into an analog signal;
the drive section is configured to perform pulse width modulation on the analog signal and then output a drive signal; and
the audio amplification section is configured to amplify the drive signal into a first amplified signal at a first amplification factor when the audio amplification section is provided with a first voltage by a first voltage source, and amplify the drive signal into a second amplified signal at a second amplification factor when the audio amplification section is provided with a second voltage by a second voltage source, wherein the first voltage of the first voltage source is lower than the second voltage of the second voltage source, and the first amplification factor is smaller than the second amplification factor.

15. An electronic device, comprising:
a chip, comprising:
a digital audio amplifier, comprising:
a digital-to-analog conversion section;
a drive section; and
an audio amplification section, wherein:
the digital-to-analog conversion section is configured to convert a to-be-amplified digital audio signal into an analog signal;
the drive section is configured to perform pulse width modulation on the analog signal and then output a drive signal; and
the audio amplification section is configured to amplify the drive signal into a first amplified signal at a first amplification factor when the audio amplification section is provided with a first voltage by a first voltage source, and amplify the drive signal into a second amplified signal at a second amplification factor when the audio amplification section is provided with a second voltage by a second voltage source, wherein the first voltage of the first voltage source is lower than the second voltage of the second voltage source, and the first amplification factor is smaller than the second amplification factor.
